(19) United States
(12) Patent Application Publication
(10) Pub. No.: US 2026/0136997 A1
(43) Pub. Date: May 14, 2026

(54) SEMICONDUCTOR PACKAGE

(71) Applicant: SAMSUNG ELECTRONICS CO., LTD., Suwon-si (KR)

(72) Inventor: Seungbin BAEK, Suwon-si (KR)

(73) Assignee: SAMSUNG ELECTRONICS CO., LTD., Suwon-si (KR)

(21) Appl. No.: 19/254,851

(22) Filed: Jun. 30, 2025

(30) Foreign Application Priority Data
Nov. 13, 2024 (KR) 10-2024-0161333

(51) Int. Cl. H01L 23/00; H01L 23/31; H01L 25/18

(52) U.S. Cl. CPC H10W 90/00; H10W 72/0198; H10W 72/072; H10W 72/07232; H10W 72/073; H10W 72/07332; H10W 72/07353; H10W 72/241; H10W 72/334; H10W 74/117; H10W 74/15; H10W 90/297; H10W 90/722; H10W 90/732; H10W 99/00

(57) ABSTRACT

A semiconductor package includes a buffer die; a plurality of first core dies and a plurality of second core dies, stacked on a first surface of the buffer die in a first direction; a bridge buffer die on the plurality of first core dies and the plurality of second core dies; and a plurality of third core dies and a plurality of fourth core dies, stacked on a surface of the bridge buffer die in the first direction, in which the plurality of first core dies are at positions symmetrical with positions of the plurality of second core dies with respect to a center line in a second direction dividing the top surface of the buffer die into two, and in which the plurality of third core dies overlap the plurality of first core dies in the first direction.

### CROSS-REFERENCE TO RELATED APPLICATION

This application is based on and claims priority under 35 U.S.C. § 119 to Korean Patent Application No. 10-2024-0161333, filed on Nov. 13, 2024, in the Korean Intellectual Property Office, the disclosure of which is incorporated by reference herein in its entirety.

### BACKGROUND

The inventive concept relates to a semiconductor package, and more particularly, to a semiconductor package including a plurality of core dies stacked in a vertical direction.

Semiconductor packages used in electronic devices are required to be miniaturized and lightweight and also required to have high performance and high capacity. To meet the demands for high performance and high capacity, there is ongoing research and development of semiconductor dies including a through-silicon via (TSV) and of semiconductor packages including semiconductor dies stacked in a vertical direction.

Recently, there has been research and development of a twin-tower-type semiconductor package in which core dies are vertically stacked in parallel on a top surface of one buffer die.

### SUMMARY

The embodiments of the present disclosure provides a semiconductor package capable of preventing warpage occurring in a high-temperature environment.

Also, the problems to be solved by the technical idea of the present embodiments of the present disclosure are not limited to those mentioned above, and the embodiments of the present disclosure can be clearly understood by those skilled in the art from the description below.

According to an aspect of the disclosure, a semiconductor package includes: a buffer die; a plurality of first core dies and a plurality of second core dies, stacked on a first surface of the buffer die in a first direction; a bridge buffer die on the plurality of first core dies and the plurality of second core dies; and a plurality of third core dies and a plurality of fourth core dies, stacked on a surface of the bridge buffer die in the first direction, in which the plurality of first core dies are at positions symmetrical with positions of the plurality of second core dies with respect to a center line in a second direction dividing the top surface of the buffer die into two, in which the plurality of third core dies overlap the plurality of first core dies in the first direction, the plurality of fourth core dies overlap the plurality of second core dies in the second direction, in which the bridge buffer die includes: a plurality of first through electrodes connecting the plurality of first core dies to the plurality of third core dies, and a plurality of second through electrodes connecting the plurality of second core dies to the plurality of fourth core dies, in which a number of the plurality of first core dies is equal to a number of the plurality of second core dies, in which a number of the plurality of third core dies is equal to a number of the plurality of fourth core dies, in which the second direction is perpendicular to a third direction from a center of the plurality of first core dies toward a center of the plurality of second core dies, and in which the second direction and the third direction are perpendicular to the first direction.

According to an aspect of the disclosure, a semiconductor package includes: a buffer die; a first core stack and a second core stack at positions symmetrical with each other with respect to a center line in a first direction dividing a first surface of the buffer die into two; and a plurality of bridge buffer dies above the buffer die and passing through the first core stack and the second core stack in a second direction, wherein a center of each of the plurality of bridge buffer dies has a coordinate corresponding to a center of the buffer die, in which each of the first core stack and the second core stack includes first to n-th core dies stacked in a third direction, where “n” is an integer exceeding 4, in which each of the plurality of bridge buffer dies is above a k-th core die and below a (k+1)-th core die among the first to n-th core dies of each of the first core stack and the second core stack, where “k” is an integer of at least 2 and less than “n”, in which the plurality of bridge buffer dies are respectively at different levels in the third direction, in which the first direction is perpendicular to the second direction from a center of the first core stack toward a center of the second core stack, and in which the third direction is perpendicular to the first direction and the second direction.

According to an aspect of the disclosure, a semiconductor package including: a buffer die; a first core stack and a second core stack at positions symmetrical with each other with respect to a center line in a first direction dividing a top surface of the buffer die into two; at least one bridge buffer die above the buffer die and passing through the first core stack and the second core stack in a second direction, wherein a center of the at least one bridge buffer die has a coordinate corresponding a center of the buffer die; and a molding layer surrounding the top surface of the buffer die, a side surface of the first core stack, and a side surface of the second core stack, in which the at least one bridge buffer die includes: a plurality of first pads, a plurality of second pads, and a plurality of first through electrodes in a first region, the plurality of first through electrodes respectively extending from the plurality of first pads to the plurality of second pads, and a plurality of third pads, a plurality of fourth pads, and a plurality of second through electrodes in a second region, the plurality of second through electrodes respectively extending from the plurality of third pads to the plurality of fourth pads, in which the first region overlaps the first core stack in a third direction, in which the second region overlaps the second core stack in the third direction, in which the first direction is perpendicular to the second direction from a center of the first core stack toward a center of the second core stack, in which at least a portion of a first surface of the at least one bridge buffer die and at least a portion of a second surface of the at least one bridge buffer die are surrounded by the molding layer, and in which the third direction is perpendicular to the first direction and the second direction.

### BRIEF DESCRIPTION OF DRAWINGS

Embodiments will be more clearly understood from the following detailed description taken in conjunction with the accompanying drawings in which:

FIG. 1 is a top view of a semiconductor package according to one or more embodiments;

FIG. 2 is a cross-sectional view of a semiconductor package according to one or more embodiments;

FIG. 3 is a cross-sectional view of a semiconductor package according to one or more embodiments;

FIG. 4 is a top view of a semiconductor package according to one or more embodiments;

FIG. 5 is a cross-sectional view of a semiconductor package according to one or more embodiments;

FIG. 6 is a cross-sectional view of a semiconductor package according to one or more embodiments;

FIG. 7 is a cross-sectional view of a semiconductor package according to one or more embodiments; and

FIGS. 8A to 8G are lateral cross-sectional views schematically illustrating a method of manufacturing a semiconductor package, according to one or more embodiments.

### DETAILED DESCRIPTION

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

Hereinafter, embodiments are described in detail with reference to the accompanying drawings. In the drawing, like reference characters denote like elements, and redundant descriptions thereof will be omitted.

In one or more examples, a horizontal direction may include a first horizontal direction (an X direction) and a second horizontal direction (a Y direction), which cross each other. A direction crossing the first horizontal direction (the X direction) and the second horizontal direction (the Y direction) may be referred to as a vertical direction (a Z direction). A vertical level may refer to a height level of an element in the vertical direction (the Z direction).

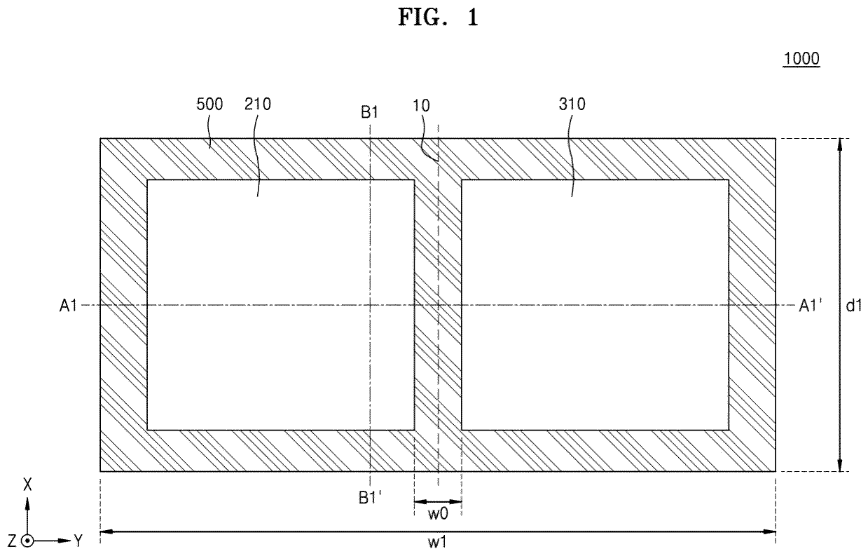

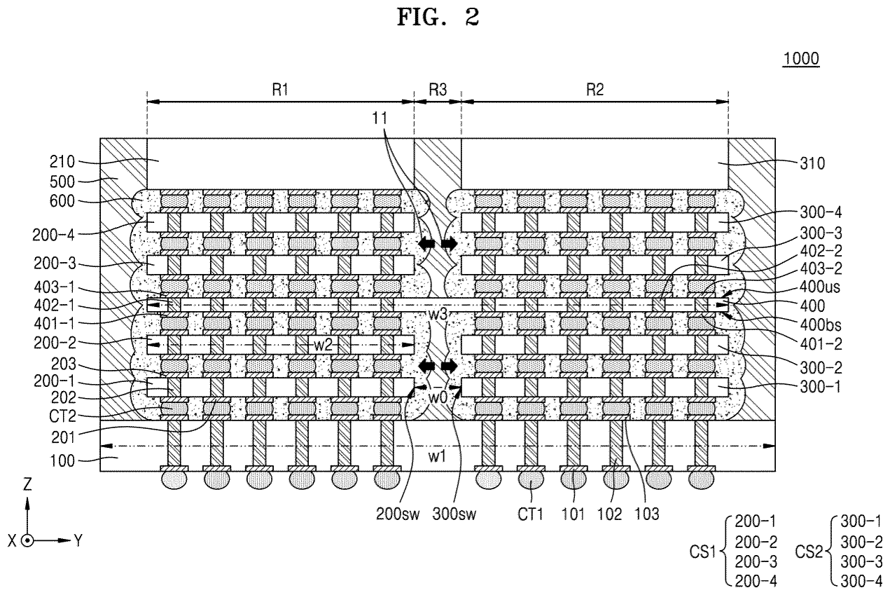

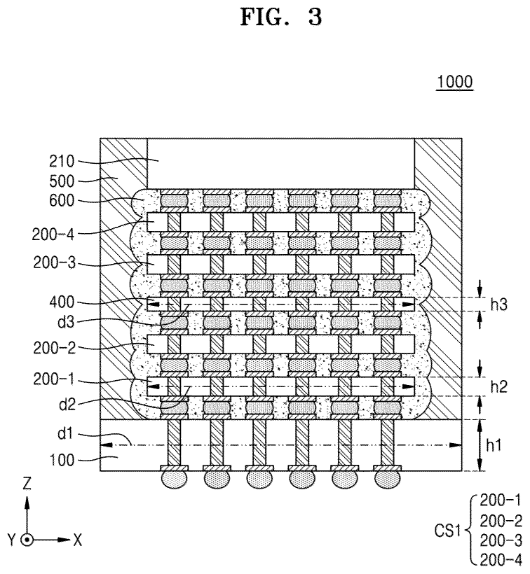

FIG. 1 is a top view of a semiconductor package 1000 according to one or more embodiments. FIG. 2 is a schematic cross-sectional view of the semiconductor package 1000, taken along line A1-A1′ in FIG. 1, according to one or more embodiments. FIG. 3 is a schematic cross-sectional view of the semiconductor package 1000, taken along line B1-B1′ in FIG. 1, according to one or more embodiments.

Referring to FIGS. 1 and 2, the semiconductor package 1000 may include a buffer die 100, a first core stack CS1, a second core stack CS2, a bridge buffer die 400, a first dummy die 210, a second dummy die 310, a molding layer 500, and an adhesive layer 600.

The buffer die 100 may be arranged in a lower portion. The first core stack CS1 and the second core stack CS2 may be arranged above the buffer die 100. The buffer die 100 may be referred to as a base die, an interface die, a logic die, and a master die. In one or more examples, the buffer die may be a piece of semiconducting material (e.g., silicon) on which electronic circuits or components are fabricated.

The buffer die 100 may include a lower buffer pad 101, a buffer through electrode 102, and an upper buffer pad 103. The lower buffer pad 101 may be connected to an external element, such as an interposer substrate or a package substrate, through a first connection terminal CT1. The upper buffer pad 103 may be connected to core dies above the buffer die 100 through a second connection terminal CT2. The buffer through electrode 102 may correspond to a path through which an electrical signal moves in the buffer die 100. As illustrated in FIG. 2, in one or more examples, the buffer die 100 may include a plurality of lower buffer pads 101, a plurality of buffer electrodes 102, and a plurality of upper buffer pads 103.

In one or more examples, the lower buffer pad 101 and the upper buffer pad 103 may include at least one metal selected from the group consisting of copper (Cu), gold (Au), nickel (Ni), tin (Sn), silver (Ag), tungsten (W), and aluminum (Al). The buffer through electrode 102 may include a metal, such as Cu, Al, or W.

The buffer die 100 may receive a command, data, a signal, and/or the like from an external controller and transmit the command, data, a signal, and/or the like to a plurality of core dies (e.g., 200-1 to 200-4 and 300-1 to 300-4) through the buffer through electrode 102. The buffer die 100 may transmit data output from the core dies (e.g., 200-1 to 200-4 and 300-1 to 300-4) to an external controller.

The bottom surface of the buffer die 100 may correspond to an active surface. For example, the buffer die 100 may be arranged in a face-down manner. However, the buffer die 100 may be arranged in a face-up manner and is not limited to the arrangements described above. In one or more examples, as illustrated in FIG. 2, the buffer die 100 may include a buffer semiconductor substrate and a buffer circuit layer on the bottom surface of the buffer semiconductor substrate.

The first core stack CS1 may include a plurality of core dies (e.g., 200-1 to 200-4). The second core stack CS2 may include a plurality of core dies (e.g., 300-1 to 300-4).

In one or more examples, the term “core stack” may refer to a structure in which a plurality of core dies are vertically stacked. The term “core die” may refer to a die vertically stacked on the buffer die 100 and may include a memory circuit. For example, the core die may refer to a memory chip including dynamic random-access memory (DRAM), static RAM (SRAM), magnetoresistive RAM (MRAM), flash memory, or any other suitable memory structure known to one of ordinary skill in the art. The core die may be referred to as a memory die or a memory chip. The semiconductor package 1000 illustrated in FIG. 2 may also incorporate 3D packaging or 3D integration to increase density and functionality.

As shown in FIG. 1, the first core stack CS1 and the second core stack CS2 may be arranged at positions symmetrical with respect to a center line 10 in the first horizontal direction (the X direction), which divides the top surface of the buffer die 100 into two. In one or more examples, the distance between the first core stack CS1 and the second core stack CS2 may be denoted by a core distance w0. In one or more examples, a region of the semiconductor package 1000 which vertically overlaps the first core stack CS1 may be referred to as a first region R1, and a region of the semiconductor package 1000 which vertically overlaps the second core stack CS2 may be referred to as a second region R2. The first region R1 may be apart from the second region R2 in the second horizontal direction (e.g., the Y direction) by the core distance w0. Although the embodiments describe that the first core stack CS1 and the second core stack CS2 are at positions symmetrical with respect to a center line that divides the buffer die 100, the embodiments are not limited to this configuration. For example, in one or more examples, the first core stack CS1 and the second core stack CS2 may be at positions that are asymmetrical with respect to the center line of the buffer die. For example, one of the first core stack CS1 or the second core stack CS2 may be closer to the center line of the buffer die.

A plurality of core dies included in each of the first core stack CS1 and the second core stack CS2 may be the same semiconductor dies. The core dies included in each of the first core stack CS1 and the second core stack CS2 may form a chip-on-wafer (COW) structure together with the buffer die 100. The bottom surface of each of the core dies included in each of the first core stack CS1 and the second core stack CS2 may correspond to an active surface. In other words, the core dies included in each of the first core stack CS1 and the second core stack CS2 may be provided in a face-down manner.

For convenience of descriptions below, the core dies (200-1 to 200-4) of the first core stack CS1 may be respectively referred to as a first-layer left core die 200-1, a second-layer left core die 200-2, a third-layer left core die 200-3, and a fourth-layer left core die 200-4. The core dies (300-1 to 300-4) of the second core stack CS2 may be respectively referred to as a first-layer right core die 300-1, a second-layer right core die 300-2, a third-layer right core die 300-3, and a fourth-layer right core die 300-4. In one or more examples, the terms “left” and “right” are used just for clarity and convenience of descriptions and should not be considered as limiting the positions of core dies in at least one embodiment. For example, the terms “left” and “right’ may be replaced with “first” and “second,” respectively, and vice versa.

A plurality of core dies of each of the first core stack CS1 and the second core stack CS2 may have the same configuration and arrangement. Accordingly, the configuration of only the first-layer left core die 200-1 is described below, and redundant descriptions are omitted from the description of the configurations of the other core dies of the first core stack CS1 and the second core stack CS2.

The first-layer left core die 200-1 may include a lower core pad 201, a core through electrode 202, and an upper core pad 203 and may be arranged such that an active surface of the first-layer left core die 200-1 faces down. The lower core pad 201 may be connected to the upper buffer pad 103 through the second connection terminal CT2. The upper core pad 203 may be connected to a lower core pad of the second-layer left core die 200-2 through the second connection terminal CT2. The core through electrode 202 may pass through the first-layer left core die 200-1 in the vertical direction (the Z direction). The core through electrode 202 may be electrically connected to a circuit layer formed in the active surface of the first-layer left core die 200-1.

The lower core pad 201 and the upper core pad 203 may include at least one metal selected from the group consisting of Cu, Au, Ni, Sn, Ag, W, and Al. The core through electrode 202 may include a metal, such as Cu, Al, or W.

The core dies of each of the first core stack CS1 and the second core stack CS2 may include the same configuration as that described above and may be connected to each other through the second connection terminal CT2 in the vertical direction (the Z direction) or may form a vertical connection to the bridge buffer die 400 through the second connection terminal CT2. The first connection terminal CT1 and the second connection terminal CT2 may include at least one selected from the group consisting of a copper bump, a copper pillar, and a solder ball.

Although it has been described that each of the core dies of each of the first core stack CS1 and the second core stack CS2 may include a memory die performing a memory function, this is just an example. The core dies of each of the first core stack CS1 and the second core stack CS2 may include various types of dies (e.g., a processing-in-memory (PIM) chip) including both a memory function and a processor function.

The bridge buffer die 400 may be above the buffer die 100 and may be arranged such that the center of the bridge buffer die 400 is aligned with the horizontal coordinate of the center of the buffer die 100. In one or more examples, the horizontal coordinate of the center of the buffer die 100 may be the same as the horizontal coordinate of the center of the bridge buffer die 400.

The bridge buffer die 400 may include a first lower pad 401-1, a second lower pad 401-2, a first through electrode 402-1, a second through electrode 402-2, a first upper pad 403-1, and a second upper pad 403-2. The first lower pad 401-1, the first through electrode 402-1, and the first upper pad 403-1 may be arranged in the first region R1. The second lower pad 401-2, the second through electrode 402-2, and the, second upper pad 403-2 may be arranged in the second region R2. As illustrated in FIG. 2, the bridge buffer die 400 may include a plurality of first lower pads 401-1, a plurality of second lower pads 401-2, a plurality of first through electrodes 402-1, a plurality of second through electrodes 402-2, a plurality of first upper pads 403-1, and a plurality of second upper pads 403-2.

The first lower pad 401-1 and the second lower pad 401-2 may be arranged on a bottom surface 400bs of the bridge buffer die 400. Each of the first lower pad 401-1 and the second lower pad 401-2 may be connected through the second connection terminal CT2 to an upper core pad of a core die below the bridge buffer die 400.

The first upper pad 403-1 and the second upper pad 403-2 may be arranged on a top surface 400us of the bridge buffer die 400. Each of the first upper pad 403-1 and the second upper pad 403-2 may be connected through the second connection terminal CT2 to a lower core pad of a core die above the bridge buffer die 400.

The first through electrode 402-1 may extend from the bottom surface of the first upper pad 403-1 to the top surface of the first lower pad 401-1 and connect the first upper pad 403-1 to the first lower pad 401-1. The second through electrode 402-2 may extend from the bottom surface of the second upper pad 403-2 to the top surface of the second lower pad 401-2 and connect the second upper pad 403-2 to second lower pad 401-2. The bridge buffer die 400 may include the first through electrode 402-1 and the second through electrode 402-2 and may thus electrically connect core dies below the bridge buffer die 400 to core dies above the bridge buffer die 400.

The first and second lower pads 401-1 and 401-2 and the first and second upper pads 403-1 and 403-2 may include at least one metal selected from the group consisting of Cu, Au, Ni, Sn, Ag, W, and Al. The first and second through electrodes 402-1 and 402-2 may include a metal, such as Cu, Al, or W.

Unlike the buffer die 100 and core dies, the bridge buffer die 400 may not include a circuit layer which may include a memory circuit and a logic circuit. Because the bridge buffer die 400 does not separately include an active device layer, a vertical thickness h3 of the bridge buffer die 400 may be less than a vertical thickness h1 of the buffer die 100, as shown in FIG. 3. The vertical thickness h3 of the bridge buffer die 400 may be less than a vertical thickness h2 of a core die. Therefore, the vertical thickness h3 of the bridge buffer die 400 may be less than the vertical thickness of any other dies. Accordingly, even when there is the bridge buffer die 400 passing through the first core stack CS1 and the second core stack CS2 in the second horizontal direction, a phenomenon in which transmission of an electrical signal in the vertical direction is delayed may be prevented as much as possible. For example, when the vertical thickness h1 of the buffer die 100 is 35 μm and the vertical thickness h2 of a core die of either the first core stack CS1 or the second core stack CS2 is 25 μm, the vertical thickness h3 of the bridge buffer die 400 may be about 15 μm to about 20 μm.

A horizontal width of the bridge buffer die 400 may be less than a horizontal width of the buffer die 100 and greater than a horizontal width of a core die of either the first core stack CS1 or the second core stack CS2. In one or more examples, the horizontal width may refer to the X direction or the Y direction illustrated in the drawings.

In one or more examples, as shown in FIG. 2, a width w3 of the bridge buffer die 400 in the second horizontal direction may be greater than twice a width w2 of the second-layer left core die 200-2 in the second horizontal direction (e.g., w3>2*w2). The width w3 of the bridge buffer die 400 in the second horizontal direction may be less than or equal to a value obtained by adding the core distance w0 to twice the width w2 of the second-layer left core die 200-2 in the second horizontal direction.

In one or more examples, the core distance w0 may refer to the distance between the first core stack CS1 and the second core stack CS2. In one or more examples, the core distance w0 may be the distance between a first side surface of the first core stack CS1 and a second side surface of the second core stack CS2. The first side surface of the first core stack CS1 may face the second core stack CS2. For example, as shown in FIG. 2, the first side surface of the first core stack CS1 may include a first sidewall 200sw of the first-layer left core die 200-1. The second side surface of the second core stack CS2 may face the first core stack CS1. For example, as shown in FIG. 2, the second side surface of the second core stack CS2 may include a second sidewall 300sw of the first-layer right core die 300-1.

As shown in FIG. 3, a width d3 of the bridge buffer die 400 in the first horizontal direction may be the same as a width d2 of the first-layer left core die 200-1 in the first horizontal direction (i.e., d3=d2) and less than a width d1 of the buffer die 100 in the first horizontal direction (i.e., d3<d1).

Because the bridge buffer die 400 has the width d3 in the first horizontal direction and the width w3 in the second horizontal direction, damage (e.g., chipping) to a die may be prevented from occurring during singulation without increasing a horizontal width of the semiconductor package 1000. The bridge buffer die 400 may also prevent warpage from occurring in the semiconductor package 1000. In one or more examples, the bridge buffer die 400 may pass through the first core stack CS1 and the second core stack CS2 in the second horizontal direction at a certain vertical level, thereby preventing crying-shaped warpage from occurring in the semiconductor package 1000.

In one or more examples, among the core dies of the first core stack CS1, core dies below the bridge buffer die 400 are referred to as “first lower core dies” and core dies above the bridge buffer die 400 are referred to as “first upper core dies”. Among the core dies of the second core stack CS2, core dies below the bridge buffer die 400 are referred to as “second lower core dies” and core dies above the bridge buffer die 400 are referred to as “second upper core dies”.

For example, as shown in FIG. 2, a plurality of first lower core dies may include the first-layer left core die 200-1 and the second-layer left core die 200-2. A plurality of second lower core dies may include the first-layer right core die 300-1 and the second-layer right core die 300-2. The number of first lower core dies may be the same as the number of second lower core dies, and the number of first upper core dies may be the same as the number of second upper core dies.

According to one or more embodiments, the number of first lower core dies may be the same as the number of first upper core dies. For example, when each of the first core stack CS1 and the second core stack CS2 may include 2n core dies stacked in the vertical direction (where “n” is a natural number or integer), the bridge buffer die 400 may be arranged above the n-th layer left and right core dies and below the (n+1)-th layer left and right core dies through the first core stack CS1 and the second core stack CS2 in the second horizontal direction. As understood by one of ordinary skill in this art, the embodiments are not limited to this configuration. For example, the number of first lower core dies may be different (e.g., greater than or less than) the number of first upper core dies.

As shown in FIG. 2, the bridge buffer die 400 may be arranged above the second-layer left and right core dies 200-2 and 300-2 and below the third-layer left and right core dies 200-3 and 300-3 through the first core stack CS1 and the second core stack CS2 in the second horizontal direction. In this case, the numbers of first lower core dies and second lower core dies may be 2, and the numbers of first upper core dies and second upper core dies may also be 2.

For example, when each of the first core stack CS1 and the second core stack CS2 may include 16 core dies stacked in the vertical direction, the bridge buffer die 400 may be arranged above eighth-layer left and right core dies and below ninth-layer left and right core dies through the first core stack CS1 and the second core stack CS2 in the second horizontal direction. In this case, the numbers of first lower core dies and second lower core dies may be 8, and the numbers of first upper core dies and second upper core dies may also be 8.

According to one or more embodiments, the number of first lower core dies may be less than the number of first upper core dies.

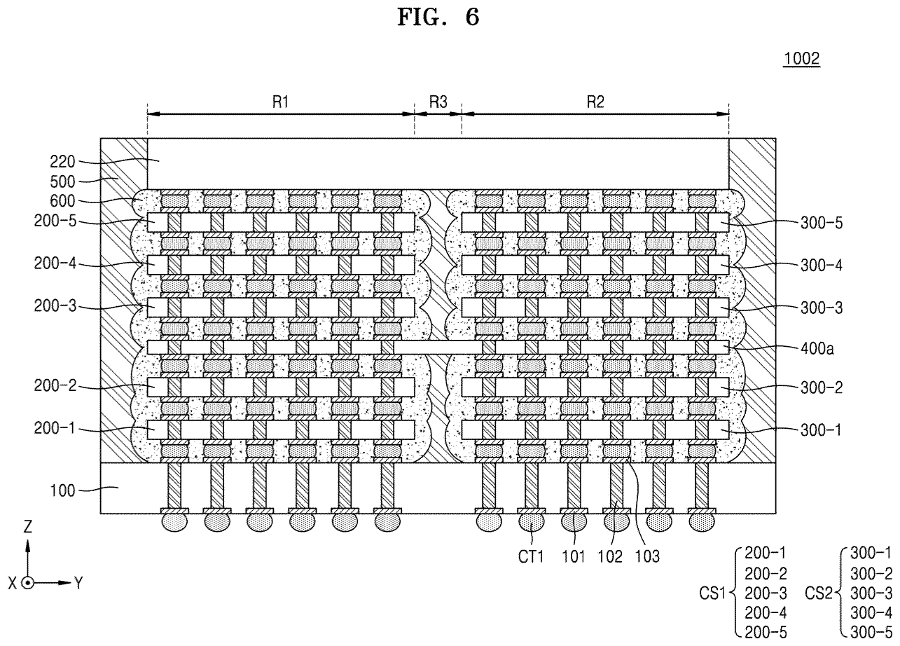

An arrangement of the semiconductor package 1000 in which the number of first lower core dies is less than the number of first upper core dies is described in detail with reference to FIG. 6 below.

The first dummy die 210 may be arranged above the first core stack CS1, and the second dummy die 310 may be arranged above the second core stack CS2. The vertical thickness of the first dummy die 210 and the second dummy die 310 may be greater than the vertical thickness of the core dies of the first core stack CS1 and the second core stack CS2. For example, the vertical thickness of the first dummy die 210 and the second dummy die 310 may be about 80 μm to about 300 μm. The top surface of each of the first dummy die 210 and the second dummy die 310 may be exposed and connected to a heat sink.

In one or more examples, as illustrated in FIG. 2, the first dummy die 210 and the second dummy die 310 may be respectively connected to the fourth-layer left and right core dies 200-4 and 300-4 through the second connection terminal CT2. In one or more examples, the first dummy die 210 and the second dummy die 310 may be respectively connected to the fourth-layer left and right core dies 200-4 and 300-4 through only the adhesive layer 600 without a connection terminal and a pad.

The molding layer 500 may surround the top surface of the buffer die 100, the side surface of the first core stack CS1, and the side surface of the second core stack CS2. The molding layer 500 may also surround the side surface of the first dummy die 210, the side surface of the second dummy die 310, and the side surface of the bridge buffer die 400.

In a third region R3, the molding layer 500 may surround at least a portion of the top surface 400us of the bridge buffer die 400 and at least a portion of the bottom surface 400bs of the bridge buffer die 400. The third region R3 may be between the first core stack CS1 and the second core stack CS2. As shown in FIG. 2, the third region R3 may extend in the vertical direction and have a width corresponding to the core distance w0 in the second horizontal direction. The molding layer 500 may include an epoxy molding compound (EMC).

The adhesive layer 600 may be configured to increase the bonding strength between adjacent core dies, the bonding strength between a core die and the bridge buffer die 400, and the bonding strength between a core die and the buffer die 100. The adhesive layer 600 may also be configured to eliminate a space that foreign substances or moisture may penetrate and prevent electrical migration.

As shown in FIGS. 2 and 3, the adhesive layer 600 may include an underfill fillet, which protrudes from the side surfaces of the first core stack CS1 and the second core stack CS2 and has an outwardly convex shape. In one or more examples, as illustrated in FIGS. 2 and 3, the underfill fillets formed at a plurality of vertical levels form a single body, this is just an example. In one or more examples, the underfill fillets may not form a single body. For example, there may be an interface in the adhesive layer 600.

According to one or more embodiments, the semiconductor package 100 may include the configuration described above, thereby preventing crying-shaped warpage from occurring in a structure core dies are stacked in a twin tower shape.

In one or more examples, in the case of a semiconductor package having a structure in which core dies are stacked in a twin tower shape, the width in the second horizontal direction is inevitably greater than the width in the first horizontal direction. Accordingly, there is a high probability that a crying-shaped warpage phenomenon, in which a central portion of the semiconductor package 1000 in the second horizontal direction (the Y direction) is convexly bent upward, disadvantageously occurs. In other words, referring to FIG. 2, the third region R3 may be bent in an upward vertical direction (a +Z direction), and thus, the left and right edges of the semiconductor package 1000 may be lower than the third region R3.

The crying-shaped warpage phenomenon described above may occur because a coefficient of thermal expansion (CTE) of the molding layer 500 and the adhesive layer 600 is different from a CTE of the buffer die 100 and the core dies of each of the first core stack CS1 and the second core stack CS2. While a CTE of silicon (Si) included in the core dies and the buffer die 100 may be about 2.6 ppm/° C. to about 2.8 ppm/° C., a CTE of an EMC included in the molding layer 500 may be about 7 ppm/° C. and a CTE of a material included in the adhesive layer 600 may be greater than 7 ppm/° C. Accordingly, in a high-temperature environment, the molding layer 500 and the adhesive layer 600 may significantly expand, while the buffer die 100 and the core dies of each of the first core stack CS1 and the second core stack CS2 may expand relatively little.

Portions of the molding layer 500 and the adhesive layer 600, which are between the first core stack CS1 and the second core stack CS2 (e.g., in the third region R3), may be exposed to higher temperature than the other portions of the molding layer 500 and the adhesive layer 600. This is because the portions of the molding layer 500 and the adhesive layer 600 in the third region R3 are exposed to heat generated from the first core stack CS1 and the second core stack CS2.

Accordingly, the portions of the molding layer 500 and the adhesive layer 600 in the third region R3 may significantly expand in a positive second horizontal direction (a +Y direction) and a negative second horizontal direction (a −Y direction). As shown in FIG. 2, the portions of the molding layer 500 and the adhesive layer 600 in the third region R3 may expand in opposite directions 11.

According to one or more embodiments, the semiconductor package 1000 may include the bridge buffer die 400 passing through the first core stack CS1 and the second core stack CS2 in the second horizontal direction, thereby suppressing the portions of the molding layer 500 and the adhesive layer 600 in the third region R3 from expanding in the opposite directions 11. In one or more examples, because a portion of the bridge buffer die 400 having a less CTE than the molding layer 500 and the adhesive layer 600 is arranged in the third region R3, expansion in the opposite directions 11 of the molding layer 500 and the adhesive layer 600 in the third region R3 may be minimally suppressed. Because the bridge buffer die 400 extends lengthwise in the second horizontal direction through the first core stack CS1 and the second core stack CS2, the structural stability of the semiconductor package 1000 in the second horizontal direction may be advantageously increased, and accordingly, crying-shaped warpage may be advantageously suppressed.

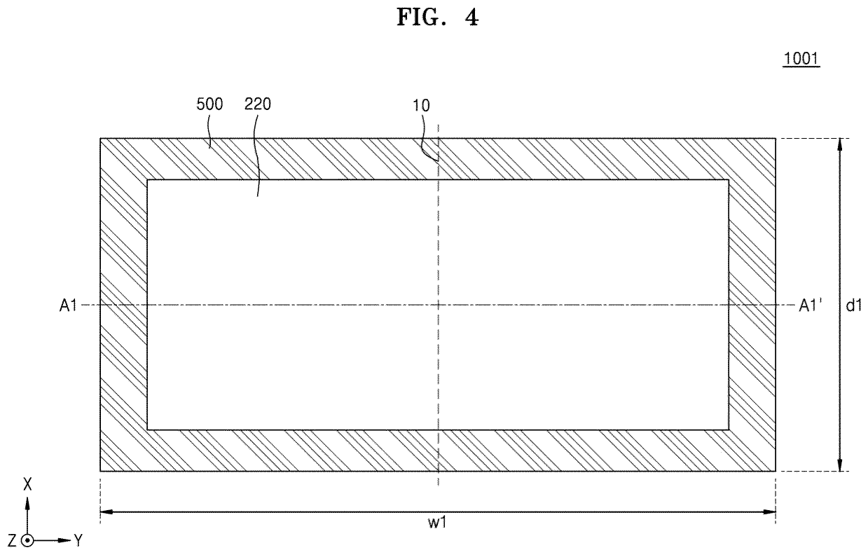

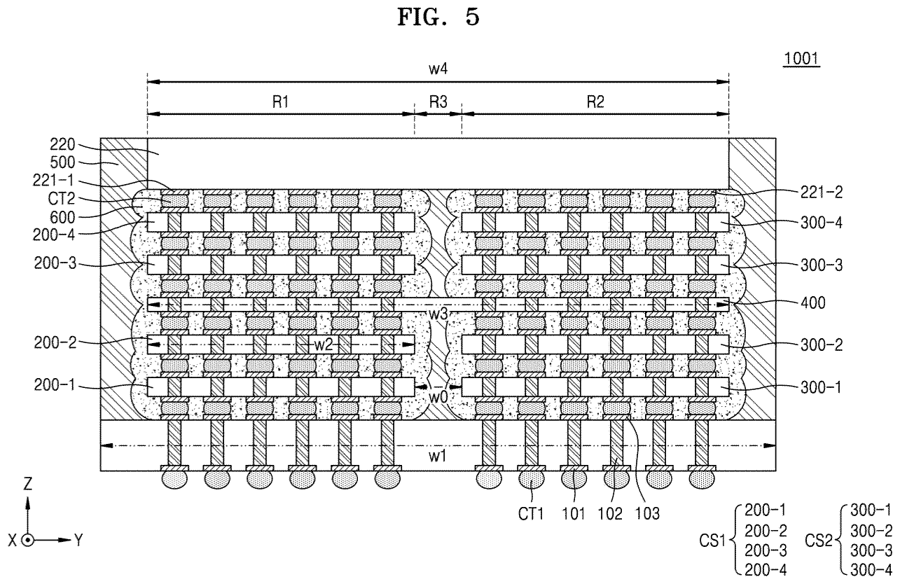

According to one or more embodiments, a semiconductor package may include a bridge dummy die, which is described in detail with reference to FIGS. 4 and 5 below.

FIG. 4 is a top view of a semiconductor package 1001 according to one or more embodiments. FIG. 5 is a cross-sectional view of the semiconductor package 1001, taken along line A1-A1′ in FIG. 4, according to one or more embodiments.

Redundant descriptions given above with reference to FIGS. 1 to 3 are omitted from the descriptions of the semiconductor package 1001 of FIGS. 4 and 5. The differences between the semiconductor package 1001 and the semiconductor package 1000 are mainly described below.

Referring to FIGS. 4 and 5, the semiconductor package 1001 may include a bridge dummy die 220.

The center of the bridge dummy die 220 may be aligned with a horizontal coordinate of the center of the buffer die 100 and the center of the bridge buffer die 400. A horizontal width of the bridge dummy die 220 may be the same as a horizontal width of the bridge buffer die 400.

In one or more examples, a width of the bridge dummy die 220 in the first horizontal direction may be the same as a width of the bridge buffer die 400 in the first horizontal direction. A width w4 of the bridge dummy die 220 in the second horizontal direction may be the same as the width w3 of the bridge buffer die 400 in the second horizontal direction.

The bridge dummy die 220 may include a first dummy pad 221-1 and a second dummy pad 221-2. The first dummy pad 221-1 may be arranged in the first region R1, and the second dummy pad 221-2 may be arranged in the second region R2. The first dummy pad 221-1 may be connected to an upper pad of a first topmost core die through the second connection terminal CT2. The second dummy pad 221-2 may be connected to an upper pad of a second topmost core die through the second connection terminal CT2. As illustrated in FIG. 5, the bridge dummy die 220 may include a plurality of first dummy pads 221-1 and a plurality of second dummy pads 221-2.

The first topmost core die may refer to the topmost core die among a plurality of core dies of the first core stack CS1. For example, as shown in FIG. 5, the fourth-layer left core die 200-4 may correspond to the first topmost core die. The second topmost core die may refer to the topmost core die among a plurality of core dies of the second core stack CS2. For example, as shown in FIG. 5, the fourth-layer right core die 300-4 may correspond to the second topmost core die.

In one or more examples, unlike the bridge buffer die 400, the bridge dummy die 220 may not include a through electrode. The vertical thickness of the bridge dummy die 220 may be greater than the vertical thickness of the bridge buffer die 400. For example the vertical thickness of the bridge dummy die 220 may be 100 μm, and the vertical thickness of the bridge buffer die 400 may be about 15 μm to about 20 μm.

The side surface of the bridge dummy die 220 may be surrounded by the molding layer 500. The top surface of the bridge dummy die 220 may be exposed without being surrounded by the molding layer 500. The top surface of the bridge dummy die 220 may be connected to a heat sink.

Although it is illustrated in FIG. 5 that the bridge dummy die 220 may be connected to each of the fourth-layer left and right core dies 200-4 and 300-4 through the second connection terminal CT2, this is just an example. The bridge dummy die 220 may be connected to the fourth-layer left and right core dies 200-4 and 300-4 through only the adhesive layer 600 without a connection terminal and a pad.

According to one or more embodiments, the semiconductor package 1001 may include the bridge dummy die 220 as well as the bridge buffer die 400, thereby suppressing crying-shaped warpage. In addition, when the area of the top surface of the bridge dummy die 220 connected to a heat sink increases, the semiconductor package 1001 may have improved heat dissipation characteristics. In one or more examples, as understood by one of ordinary skill in the art, a heat sink may be a heat exchanger that transfers heat generated by the semiconductor package 1001 to a fluid medium such as air or liquid coolant.

FIG. 6 is a cross-sectional view of the semiconductor package 1002 according to one or more embodiments. Redundant descriptions given above with reference to FIGS. 1 to 4 are omitted from the descriptions of the semiconductor package 1002 of FIG. 6. The differences between the semiconductor package 1002 and each of the semiconductor packages 1000 and 1001 are mainly described below.

Referring to FIG. 6, the semiconductor package 1002 may include a bridge buffer die 400a. The number of core dies below the bridge buffer die 400a may be less than the number of core dies above the bridge buffer die 400a.

According to one or more embodiments, when each of the first core stack CS1 and the second core stack CS2 may include 2n+1 core dies stacked in the vertical direction (where “n” is a natural number), the bridge buffer die 400a may be arranged above n-th-layer left and right core dies and below an (n+1)-th-layer left and right core dies and may pass through the first core stack CS1 and the second core stack CS2 in the second horizontal direction. In this case, the numbers of first lower core dies and second lower core dies may be “n”, and the numbers of first upper core dies and second upper core dies may be n+1.

For example, as shown in FIG. 6, the bridge buffer die 400a may be arranged above the second-layer left and right core dies 200-2 and 300-2 and below the third-layer left and right core dies 200-3 and 300-3 and may pass through the first core stack CS1 and the second core stack CS2 in the second horizontal direction. In this case, the numbers of first lower core dies and second lower core dies may be 2, and the numbers of first upper core dies and second upper core dies may be 3.

For example, when each of the first core stack CS1 and the second core stack CS2 may include 17 core dies stacked in the vertical direction, the bridge buffer die 400a may be arranged above eighth-layer left and right core dies and below ninth-layer left and right core dies and may pass through the first core stack CS1 and the second core stack CS2 in the second horizontal direction. In this case, the numbers of first lower core dies and second lower core dies may be 8, and the numbers of first upper core dies and second upper core dies may be 9.

According to one or more embodiments, the bridge buffer die 400a may be arranged above the second-layer left and right core dies 200-2 and 300-2 and below the third-layer left and right core dies 200-3 and 300-3, regardless of the number of core dies included in each of the first core stack CS1 and the second core stack CS2.

For example,, even when the number of layers stacked in the vertical direction increases in the first core stack CS1 and the second core stack CS2, the bridge buffer die 400a may be adjacent to the buffer die 100. Accordingly, the buffer die 100 having the greatest width in the second horizontal direction may be maximally suppressed from warping.

Although various arrangements in which the bridge buffer die 400a passes through the first core stack CS1 and the second core stack CS2 in the second horizontal direction have been described above, these are just examples. The bridge buffer die 400a may pass through the first core stack CS1 and the second core stack CS2 in the second horizontal direction in other various arrangements.

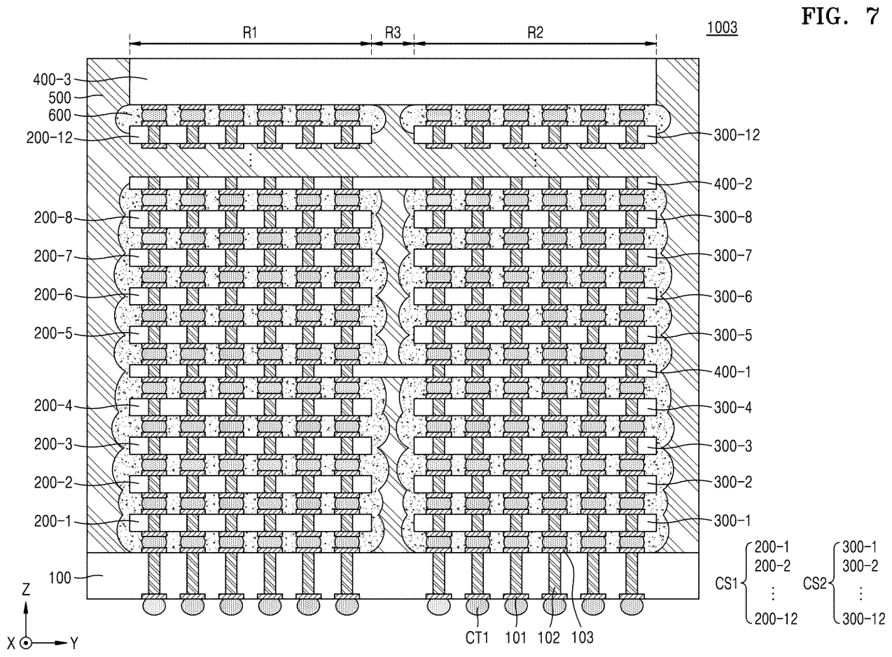

A semiconductor package including a plurality of bridge buffer dies is described below with reference to FIG. 7.

FIG. 7 is a cross-sectional view of the semiconductor package 1003 according to one or more embodiments. Redundant descriptions given above are omitted from the descriptions of the semiconductor package 1003 of FIG. 7. The differences between the semiconductor package 1003 and each of the semiconductor packages 1000, 1001, and 1002 are mainly described below.

Each of the first core stack CS1 and the second core stack CS2 may include first to n-th core dies stacked in the vertical direction (where “n” is a natural number exceeding 4). The semiconductor package 1003 may include a plurality bridge buffer dies at different vertical levels.

Each of the bridge buffer dies may be arranged above a k-th core die of each of the first core stack CS1 and the second core stack CS2 and below a (k+1)-th core die of each of the first core stack CS1 and the second core stack CS2 (where “k” is a natural number of at least 2 and less than “n”).

According to one or more embodiments, when each of the first core stack CS1 and the second core stack CS2 may include first to 16th core dies (i.e., n=16), three bridge buffer dies may be arranged at different vertical levels. In one or more examples, a first bridge buffer die may be arranged above a third core die of each of the first core stack CS1 and the second core stack CS2 and below a fourth core die thereof, a second bridge buffer die may be arranged above a sixth core die of each of the first core stack CS1 and the second core stack CS2 and below a seventh core die thereof, and a third bridge buffer die may be arranged above a eleventh core die of each of the first core stack CS1 and the second core stack CS2 and below a twelfth core die thereof (k=3, 6, 11).

Although it has been described above that a plurality of bridge buffer dies may be arranged respectively between the third and fourth layers, between the sixth and seventh layers, and between the eleventh and twelfth layers, this is just an example. A plurality of bridge buffer dies may be arranged at vertical levels such that warpage may be maximally prevented and the movement of an electrical signal in the vertical direction is not delayed. For example, a plurality of bridge buffer dies may be arranged at regular intervals in the vertical direction.

According to one or more embodiments, whenever “m” layers of core dies are stacked, a bridge buffer die may be arranged through the first core stack CS1 and the second core stack CS2 in the second horizontal direction. Accordingly, “m” core dies of each of the first core stack CS1 and the second core stack CS2 may be between two adjacent bridge buffer dies among the plurality of bridge buffer dies. In addition, “m” core dies of each of the first core stack CS1 and the second core stack CS2 may be between the buffer die 100 and the bottommost bridge buffer die at the bottom among the plurality of bridge buffer dies. In one or more examples, “n” may be a natural number exceeding 4, and “m” is a natural number of at least 2 and at most n/2 (i.e.,

$$2 \leq m \leq \frac{n}{2} ,$$

and “m” is a natural number).

In this case, the number of bridge buffer dies may be [n/m]. In one or more examples, the brackets [ ] may correspond to a greatest integer function. For example, [x] may indicate the greatest integer that does not exceed “x”.

According to one or more embodiments, as shown in FIG. 7, “n” may be 12 and “m” may be 4. In this case, there may be three bridge buffer dies. In other words, the first core stack CS1 may include first- to twelfth-layer left core dies 200-1 to 200-12 stacked in the vertical direction, and the second core stack CS2 may include first-to twelfth-layer right core dies 300-1 to 300-12 stacked in the vertical direction. In this case, the three bridge buffer dies may include a first bridge buffer die 400-1, a second bridge buffer die 400-2, and a third bridge buffer die 400-3. The first bridge buffer die 400-1 may be arranged above the fourth-layer left and right core dies 200-4 and 300-4 and below the fifth-layer left and right core dies 200-5 and 300-5. The second bridge buffer die 400-2 may be arranged above the eighth-layer left and right core dies 200-8 and 300-8 and below the ninth-layer left and right core dies 200-9 and 300-9, and the third bridge buffer die 400-3 may be arranged above the twelfth-layer left and right core dies 200-12 and 300-12.

According to one or more embodiments, “n” may be 12 and “m” may be 5. In this case, there may be two bridge buffer dies. In one or more examples, the first bridge buffer die 400-1 may be arranged above the fifth-layer left and right core dies 200-5 and 300-5 and below the sixth-layer left and right core dies 200-6 and 300-6, and the second bridge buffer die 400-2 may be arranged above the tenth-layer left and right core dies 200-10 and 300-10 and below the eleventh-layer left and right core dies 200-11 and 300-11.

According to one or more embodiments, “n” may be 16 and “m” may be 5. In this case, there may be three bridge buffer dies. Whenever five layers of core dies are stacked, a bridge buffer die may be arranged through the first core stack CS1 and the second core stack CS2 in the second horizontal direction.

According to one or more embodiments, “n” may be 20 and “m” may be 6. In this case, there may be three bridge buffer dies. Whenever six layers of core dies are stacked, a bridge buffer die may be arranged through the first core stack CS1 and the second core stack CS2 in the second horizontal direction.

Each of the first bridge buffer die 400-1 and the second bridge buffer die 400-2 has the same configuration as the bridge buffer die 400 described with reference to FIGS. 1 to 3, and thus, redundant descriptions thereof are omitted.

However, the third bridge buffer die 400-3 above the first core stack CS1 and the second core stack CS2 may include neither a through electrode nor an upper pad. The top surface of the third bridge buffer die 400-3 may be exposed without being surrounded by the molding layer 500. The vertical thickness of the third bridge buffer die 400-3 above the first core stack CS1 and the second core stack CS2 may be greater than the vertical thickness h3 of the bridge buffer die 400 in FIGS. 1 to 3.

As described above, the semiconductor package 1003 may include a plurality of bridge buffer dies that are arranged through the first core stack CS1 and the second core stack CS2 in the second horizontal direction whenever “m” layers of core dies are stacked. Accordingly, even when the number of layers in the first core stack CS1 and the second core stack CS2 increases, the structural stability may be improved, and crying-shaped warpage may be suppressed.

The embodiments described above are just examples of various structures in which a plurality of bridge buffer dies may be stacked. The embodiments of the present disclosure is not limited thereto, and a plurality of bridge buffer dies may be arranged in various manners.

Although it has been described with reference to FIGS. 1 to 7 that bonding between core dies, bonding between a core die and the bridge buffer die 400, and bonding between a core die and the buffer die 100 may be carried out through the second connection terminal CT2, this is just an example. Bonding between core dies, bonding between a core die and the bridge buffer die 400, and bonding between a core die and the buffer die 100 may be carried out through various bonding structures.

For example, bonding between core dies, bonding between a core die and the bridge buffer die 400, and bonding between a core die and the buffer die 100 may be carried out through hybrid bonding. In this case, the second connection terminal CT2 and the adhesive layer 600 may be omitted.

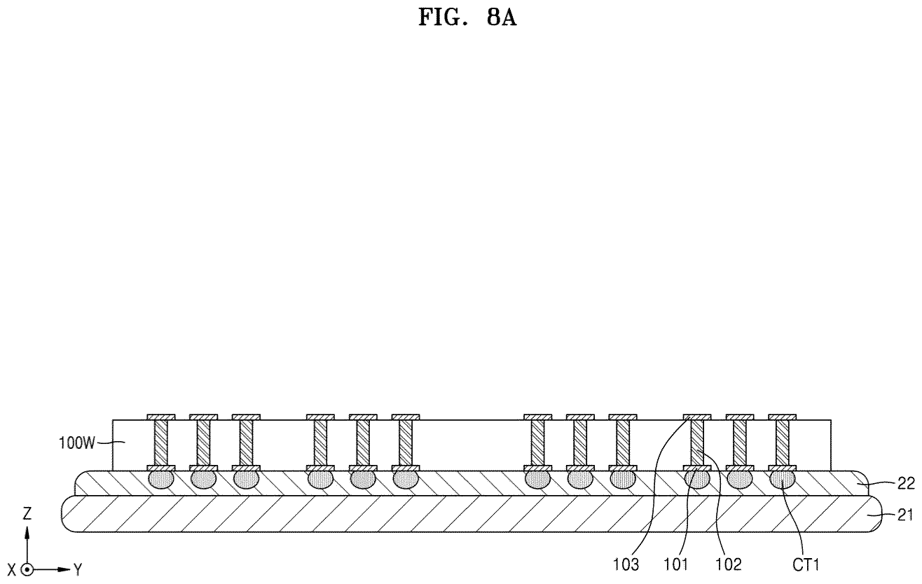

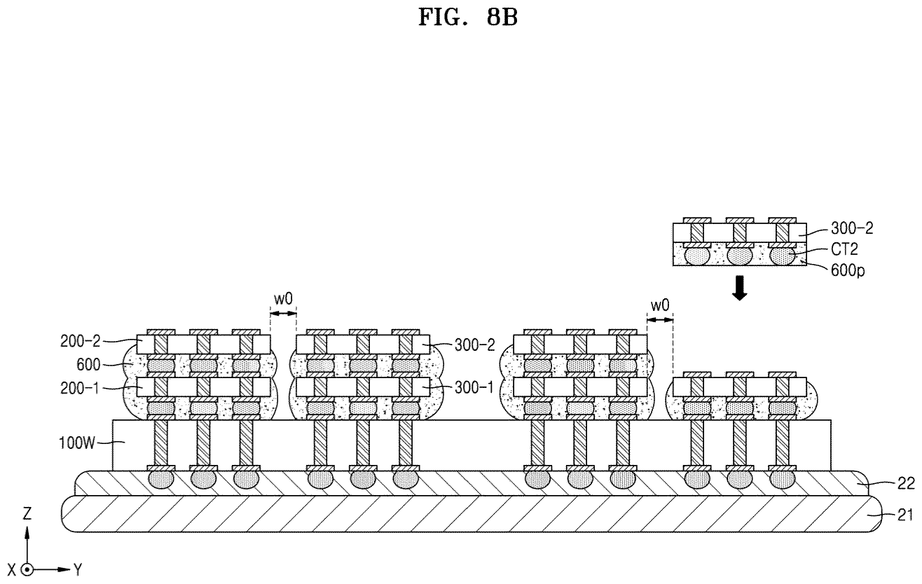

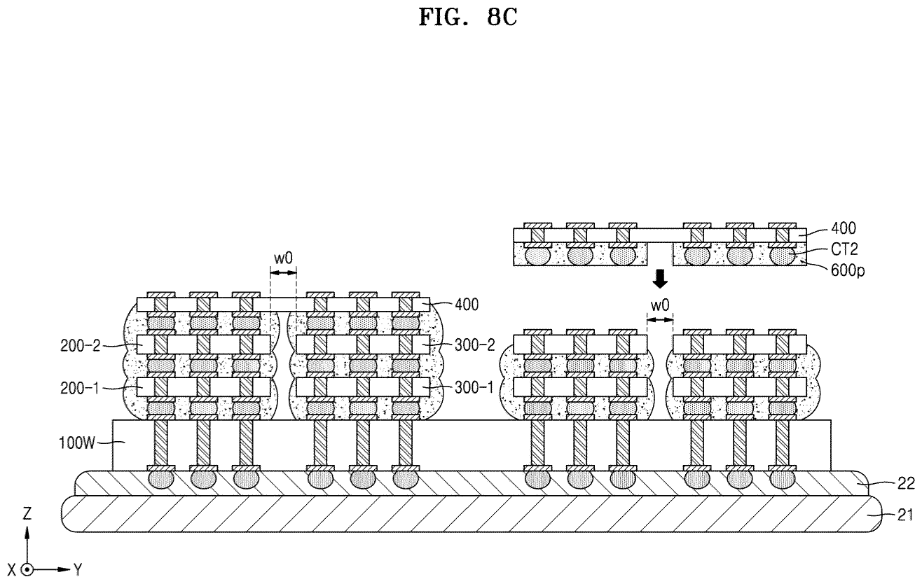

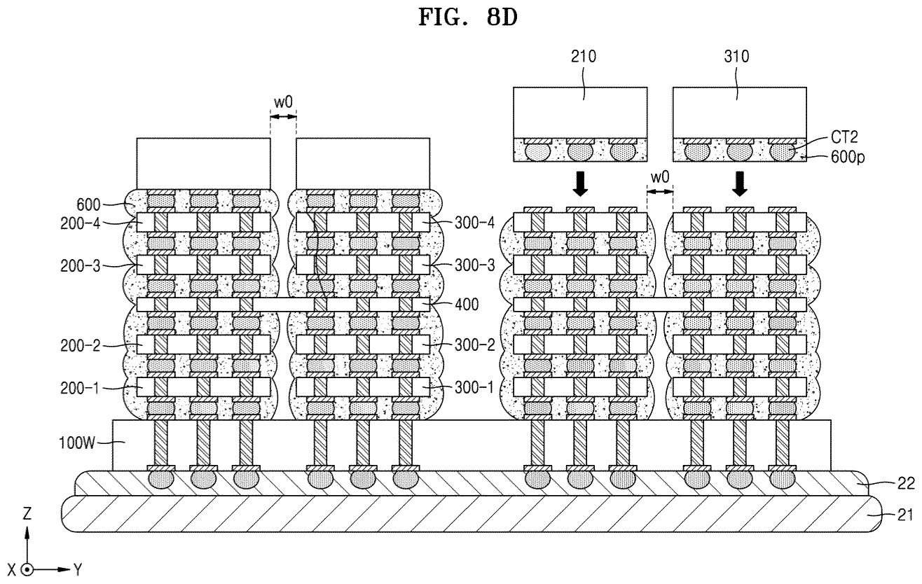

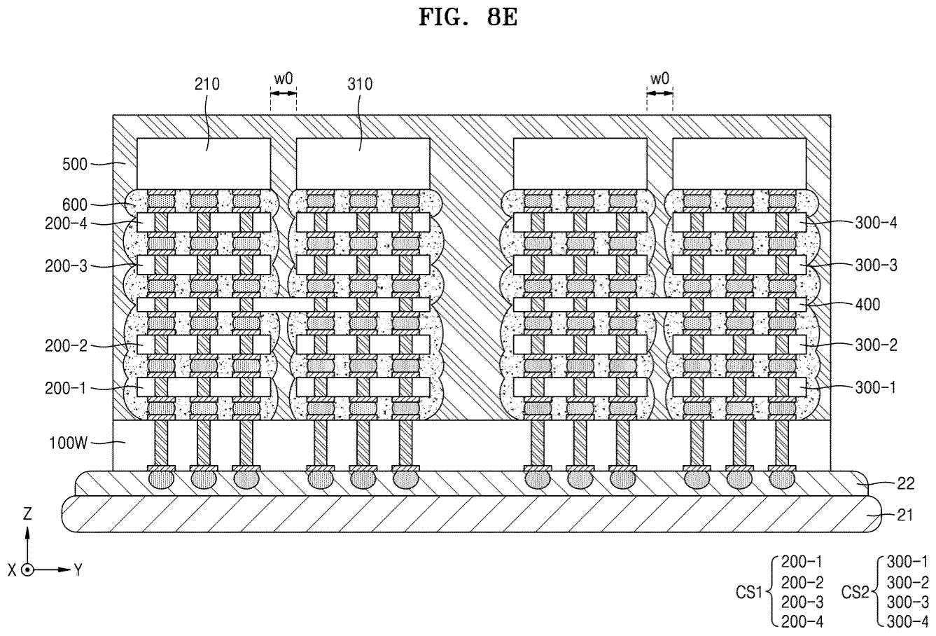

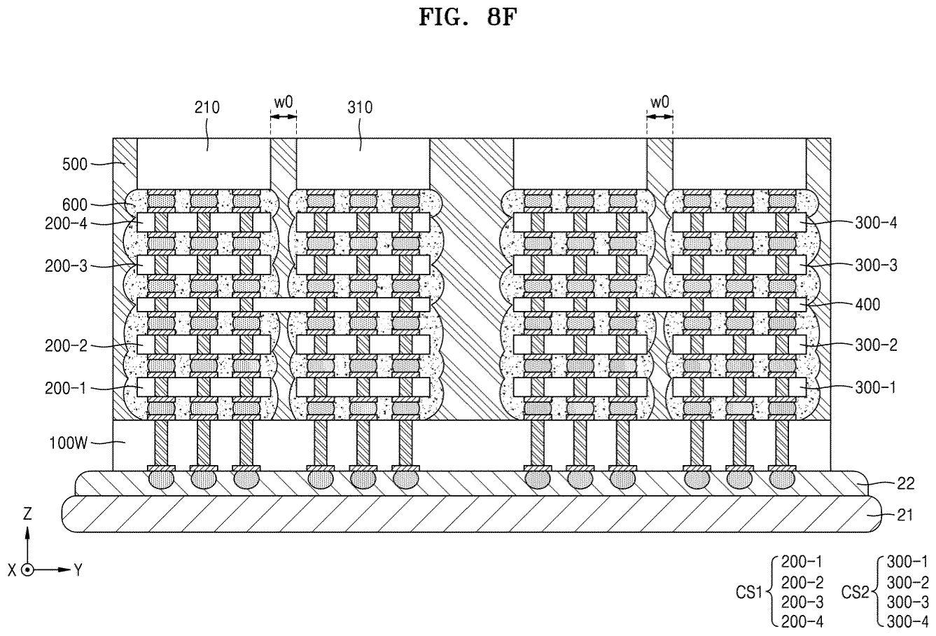

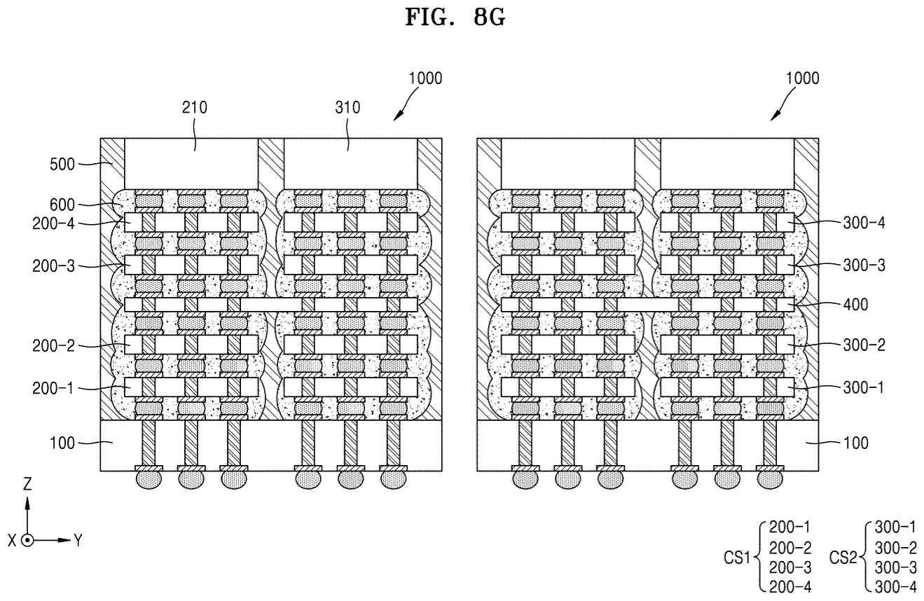

FIGS. 8A to 8G are lateral cross-sectional views schematically illustrating a method of manufacturing a semiconductor package, according to one or more embodiments.

Referring to FIG. 8A, a semiconductor substrate 100W may be attached to a carrier substrate 21.

For example, the carrier substrate 21 may include silicon (e.g., a blank device wafer), soda lime glass, borosilicate glass, silicon carbide, silicon germanium, silicon nitride, gallium arsenide, sapphire, a metal, or ceramic. However, the carrier substrate 21 is not limited to those mentioned above.

The semiconductor substrate 100W may include a semiconductor, such as silicon (Si) or germanium (Ge), or a compound semiconductor, such as SiGe, SiC, GaAs, InAs, or InP, and may be arranged such that an active surface of the semiconductor substrate 100W, on which a semiconductor device is formed, faces the carrier substrate 21.

The semiconductor substrate 100W may be attached to the carrier substrate 21 by a binder 22. The binder 22 may include a general adhesive containing a polysiloxane-based compound and may bond the carrier substrate 21 to the semiconductor substrate 100W with sufficient strength.

Referring to FIG. 8B, a plurality of first lower core dies (e.g., 200-1 and 200-2 and a plurality of second lower core dies (e.g., 300-1 and 300-2) may be stacked on the semiconductor substrate 100W in the vertical direction.

The first lower core dies (200-1 and 200-2) and the second lower core dies (300-1 and 300-2) may be stacked through a pick-and-place process. In other words, each of the first lower core dies (200-1 and 200-2) and the second lower core dies (300-1 and 300-2) may be picked up and placed at a desired position on the top surface of the semiconductor substrate 100W.

When each of the first lower core dies (200-1 and 200-2) and the second lower core dies (300-1 and 300-2) is placed, the second connection terminal CT2 and an adhesive sheet 600p may be placed on the bottom surface of each core die. The adhesive sheet 600p may include a non-conductive film (NCF).

After a core die having the adhesive sheet 600p on the bottom surface thereof is placed above another core die or the semiconductor substrate 100W, a thermal compression process may be carried out. For example, after a core die having the adhesive sheet 600p on the bottom surface thereof is arranged above another core die, heat and pressure may be applied to the core die having the adhesive sheet 600p by using a bonding head.

Due to the application of heat and pressure using the bonding head, the adhesive sheet 600p may be fluid through reflow and may thus flow toward the periphery of the core die. In this case, the adhesive sheet 600p may protrude outward from the side surface of the core die. In addition, the adhesive sheet 600p protruding outward may be amalgamated with an underfill fillet, which has been formed below the adhesive sheet 600p, thereby forming the adhesive layer 600.

However, the thermal compression process using a bonding head is just an example, and various methods may be used to bond a core die.

Although it is illustrated in FIG. 8B that the numbers of first lower core dies (200-1 and 200-2) and second lower core dies (300-1 and 300-2) are 2, the numbers of first lower core dies and second lower core dies may vary, as described above with reference to FIGS. 1 to 7.

Referring to FIG. 8C, the bridge buffer die 400 may be arranged above the first lower core dies (200-1 and 200-2) and the second lower core dies (300-1 and 300-2).

The bridge buffer die 400 may be arranged through the pick-and-place process described above. In one or more examples, the bridge buffer die 400 may be aligned such that the center of the bridge buffer die 400 has the same horizontal coordinate as the center between the first lower core dies (200-1 and 200-2) and the second lower core dies (300-1 and 300-2).

When the bridge buffer die 400 is arranged above a core die, the second connection terminal CT2 and the adhesive sheet 600p may be arranged on the bottom surface of the bridge buffer die 400, and a thermal compression process using a bonding head may be carried out.

Referring to FIG. 8D, a plurality of first upper core dies (e.g., 200-3 and 200-4) and a plurality of second upper core dies (e.g., 300-3 and 300-4) may be arranged above the bridge buffer die 400. The first dummy die 210 may be arranged above the first upper core dies (200-3 and 200-4), and the second dummy die 310 may be arranged above the second upper core dies (300-3 and 300-4).

The pick-and-place process described above may be used when the first upper core dies (200-3 and 200-4) and the second upper core dies (300-3 and 300-4) are arranged above the bridge buffer die 400 and when first dummy die 210 is arranged above the first upper core dies (200-3 and 200-4) and the second dummy die 310 is arranged above the second upper core dies (300-3 and 300-4).

The second connection terminal CT2 and the adhesive sheet 600p may be arranged on the bottom surface of each of the first lower core dies (200-1 and 200-2), the second lower core dies (300-1 and 300-2), the first dummy die 210, and the second dummy die 310. After the first upper core dies (200-3 and 200-4), the second upper core dies (300-3 and 300-4), the first dummy die 210, and the second dummy die 310 are arranged, the thermal compression process described above may be carried out.

It has been described with reference to FIGS. 8B to 8D that an operation (referred to as a first operation) of stacking the first lower core dies (200-1 and 200-2) and the second lower core dies (300-1 and 300-2), an operation (referred to as a second operation) of stacking the bridge buffer die 400, an operation (referred to as a third operation) of stacking the first upper core dies (200-3 and 200-4) and the second upper core dies (300-3 and 300-4), and an operation (a fourth operation) of stacking the first dummy die 210 and the second dummy die 310 may be sequentially performed. However, the first to third operations may be repeatedly performed.

For example, after the first to third operations are sequentially performed “n” times (where “n” is a natural number of at least 2), the fourth operation may be performed. In this case, the number of dies stacked in each of the first and third operations may be 1 to 10.

As described above, when the first to third operations are sequentially and repeatedly performed, a plurality of bridge buffer dies may be included in a semiconductor package, and thus the semiconductor package 1003 of FIG. 7 may be manufactured. In the fourth operation, instead of the first dummy die 210 and the second dummy die 310, the bridge dummy die 220 in FIG. 5 may be stacked.

Although it is described with reference to FIGS. 8B to 8D that a bonding process may be carried out using the second connection terminal CT2 and the adhesive sheet 600p, this is just an example. Bonding between core dies, bonding between a core die and the bridge buffer die 400, and bonding between a core die and the buffer die 100 may be carried out using a hybrid bonding process.

The hybrid bonding process may refer to combination of pad-to-pad bonding, in which an upper pad directly contacts a lower pad, and insulator-to-insulator bonding, in which an upper insulating layer directly contacts a lower insulating layer.

Referring to FIG. 8E, the molding layer 500 may be formed to surround the side surface of the first core stack CS1, the side surface of the second core stack CS2, and the side and top surfaces of the first dummy die 210 and the second dummy die 310.

Referring to FIG. 8F, the molding layer 500 may be ground to expose the top surfaces of the first dummy die 210 and the second dummy die 310. The molding layer 500 may be ground using chemical mechanical polishing (CMP) or the like.

Referring to FIG. 8G, after the carrier substrate 21 is removed, singulation may be carried out to obtain individual semiconductor packages (e.g., dicing may be performed to obtain individual semiconductor packages).

The carrier substrate 21 may be removed by applying an external force to the binder 22 such that a crack occurs in the surface of the binder 22. For example, an impact may be applied to the binder 22 by using a blade or an initiator such that a crack occurs in the surface of the binder 22. Once a crack occurs, the crack may propagate, so that the carrier substrate 21 may be removed.

The singulation may be carried by sawing but is not limited thereto. For example, the singulation may be carried out by laser irradiation.

Through the singulation, a single semiconductor package may include the first core stack CS1, the second core stack CS2, and the bridge buffer die 400 which passes through the first core stack CS1 and the second core stack CS2 in the second horizontal direction so as to increase structural stability.

As described above, according to one or more embodiments, a semiconductor package may include the bridge buffer die 400 which passes through the first core stack CS1 and the second core stack CS2 in the second horizontal direction at a certain vertical level so as to increase structural stability, thereby suppressing crying-shaped warpage.

The specification describes components as being “lower,” “upper,” “horizontal,” “vertical,” etc. In one or more examples, these components may be alternatively disclosed as:

| Original Term | Alternative Term |
|---|---|
| plurality of first lower core dies | plurality of first core dies |
| plurality of second lower core dies | plurality of second core dies |
| plurality of first upper core dies | plurality of third core dies |
| plurality of second upper core dies | plurality of fourth core dies |
| vertical direction | first direction |
| first horizontal direction | second direction |
| second horizontal direction | third direction |
| horizontal width | width |
| vertical thickness | thickness |
| plurality of first upper pads | plurality of first pads |
| plurality of second upper pads | plurality of second pads |
| plurality of first lower pads | plurality of third pads |
| plurality of second lower pads | plurality of fourth pads |

While the embodiments of the present disclosure has been particularly shown and described with reference to embodiments thereof, it will be understood that various changes in form and details may be made therein without departing from the spirit and scope of the following claims.

What is claimed is:

1. A semiconductor package comprising:
a buffer die;
a plurality of first core dies and a plurality of second core dies, stacked on a first surface of the buffer die in a first direction;
a bridge buffer die on the plurality of first core dies and the plurality of second core dies; and
a plurality of third core dies and a plurality of fourth core dies, stacked on a surface of the bridge buffer die in the first direction,
wherein the plurality of first core dies are at positions symmetrical with positions of the plurality of second core dies with respect to a center line in a second direction dividing the top surface of the buffer die into two,
wherein the plurality of third core dies overlap the plurality of first core dies in the first direction,
wherein the plurality of fourth core dies overlap the plurality of second core dies in the second direction,
wherein the bridge buffer die comprises:
a plurality of first through electrodes connecting the plurality of first core dies to the plurality of third core dies, and
a plurality of second through electrodes connecting the plurality of second core dies to the plurality of fourth core dies,
wherein a number of the plurality of first core dies is equal to a number of the plurality of second core dies,
wherein a number of the plurality of third core dies is equal to a number of the plurality of fourth core dies,
wherein the second direction is perpendicular to a third direction from a center of the plurality of first core dies toward a center of the plurality of second core dies, and
wherein the second direction and the third direction are perpendicular to the first direction.

2. The semiconductor package of claim 1, wherein:
the number of the plurality of first core dies is less than the number of the plurality of third core dies, and
the number of the plurality of second core dies is less than the number of the plurality of fourth core dies.

3. The semiconductor package of claim 1, wherein:
a center of the bridge buffer die is positioned at a coordinate that is the same as that of a center of the buffer die,
a width of the bridge buffer die is less than a width of the buffer die,
the width of the bridge buffer die is greater than a width of each of the plurality of first core dies, and
the width of each of the plurality of first core dies is equal to a horizontal width of each of the plurality of first upper core dies, the plurality of second lower core dies, and the plurality of second upper core dies.

4. The semiconductor package of claim 1, wherein:
a width of the bridge buffer die in the second direction is equal to a width of each of the plurality of first core dies in the second direction,
a width of the bridge buffer die in the third direction is greater than twice a width of each of the plurality of first core dies in the third direction,
a width of each of the plurality of first core dies in the second direction is equal to a width of each of the plurality of third core dies, the plurality of second core dies, and the plurality of fourth core dies in the second direction, and
a width of each of the plurality of first core dies in the third direction is equal to a width of each of the plurality of third core dies, the plurality of second core dies, and the plurality of fourth core dies in the third direction.

5. The semiconductor package of claim 4, wherein:
the width of the bridge buffer die in the third direction is less than or equal to a value obtained by adding a core distance to twice the width of each of the plurality of first core dies in the third direction,
the core distance corresponds to a distance between a first sidewall of each of the plurality of first core dies and a second sidewall of each of the plurality of second core dies,
each first sidewall of the plurality of first core dies faces a respective second core die from the plurality of second core dies, and
each second sidewall of the plurality of second core dies faces a respective first core die from the plurality of first core dies.

6. The semiconductor package of claim 3, wherein
a thickness of the bridge buffer die in the first direction is less than a thickness of each of the plurality of first core dies, the plurality of second core dies, the plurality of third core dies, and the plurality of fourth core dies in the first direction.

7. The semiconductor package of claim 1, wherein
the bridge buffer die further comprises:
a plurality of first pads and a plurality of second pads, on the first surface of the bridge buffer die, and
a plurality of third pads and a plurality of fourth pads, on a second surface of the bridge buffer die,
each of the plurality of first through electrodes extends from a first surface of each of the plurality of first pads to a second surface of each of the plurality of third pads, and
each of the plurality of second through electrodes extends from a first surface of each of the plurality of second pads to a second surface of each of the plurality of fourth pads.

8. The semiconductor package of claim 7, wherein:
the plurality of first through electrodes, the plurality of first pads, and the plurality of third pads are in a first region,
the plurality of second through electrodes, the plurality of fourth pads, and the plurality of fourth pads are in a second region,
the first region overlaps the plurality of first core dies and the plurality of third core dies in the first direction, and
the second region overlaps the plurality of second core dies and the plurality of fourth core dies in the first direction.

9. The semiconductor package of claim 1, further comprising:
a bridge dummy die above a first topmost core die and a second topmost core die, the first topmost core die being an uppermost third core die from the plurality of third core dies,
wherein the bridge dummy die comprises a plurality of first dummy pads and a plurality of second dummy pads on a first surface of the bridge dummy die,
each of the plurality of first dummy pads is connected to an upper pad of the first topmost core die,
each of the plurality of second dummy pads is connected to an upper pad of the second topmost core die, and
the second topmost core die is an uppermost fourth core die from the plurality of fourth core dies.

10. The semiconductor package of claim 9, wherein:
a width of the bridge dummy die in the second direction is equal to a width of the bridge buffer die in the second direction, and
a width of the bridge dummy die in the third direction is equal to a width of the bridge buffer die in the third direction.

11. A semiconductor package comprising:
a buffer die;
a first core stack and a second core stack at positions symmetrical with each other with respect to a center line in a first direction dividing a first surface of the buffer die into two; and
a plurality of bridge buffer dies above the buffer die and passing through the first core stack and the second core stack in a second direction, wherein a center of each of the plurality of bridge buffer dies has a coordinate corresponding to a center of the buffer die,
wherein each of the first core stack and the second core stack includes first to n-th core dies stacked in a third direction, where “n” is an integer exceeding 4,
wherein each of the plurality of bridge buffer dies is above a k-th core die and below a (k+1)-th core die among the first to n-th core dies of each of the first core stack and the second core stack, where “k” is an integer of at least 2 and less than “n”,
wherein the plurality of bridge buffer dies are respectively at different levels in the third direction,
wherein the first direction is perpendicular to the second direction from a center of the first core stack toward a center of the second core stack, and
wherein the third direction is perpendicular to the first direction and the second direction.

12. The semiconductor package of claim 11, wherein:
“m” core dies of each of the first core stack and the second core stack are between two adjacent bridge buffer dies among the plurality of bridge buffer dies, where 2≤m≤n/2 and “m” is an integer,
core dies other than the “m” core dies of each of the first core stack and the second core stack are between the buffer die and a bottommost bridge buffer die that is bottommost among the plurality of bridge buffer dies, and
a number of the plurality of bridge buffer dies is n/m.

13. The semiconductor package of claim 12, wherein “n” is 12, and “m” is 4 to 6.

14. The semiconductor package of claim 12, wherein “n” is 16, and “m” is 5 to 8.

15. The semiconductor package of claim 12, wherein “n” is 20, and “m” is 6 to 10.

16. The semiconductor package of claim 11, wherein:
a width of each of the plurality of bridge buffer dies is less than a width of the buffer die, and
the width of each of the plurality of bridge buffer dies is greater than a width of each of the first core stack and the second core stack.

17. The semiconductor package of claim 11, wherein:
a width of each of the plurality of bridge buffer dies in the first direction is equal to a width of each of the first core stack and the second core stack in the first direction, and
a width of each of the plurality of bridge buffer dies in the second direction is greater than twice a width of each of the first core stack and the second core stack in the second direction.

18. The semiconductor package of claim 17, wherein:
the width of each of the plurality of bridge buffer dies in the second direction is less than or equal to a value obtained by adding a core distance to twice the width of each of the first core stack and the second core stack in the second direction,
the core distance corresponds to a distance between a first side surface of the first core stack and a second side surface of the second core stack,
the first side surface of the first core stack faces the second core stack, and
the second side surface of the second core stack faces the first core stack.

19. A semiconductor package comprising:
a buffer die;
a first core stack and a second core stack at positions symmetrical with each other with respect to a center line in a first direction dividing a top surface of the buffer die into two;
at least one bridge buffer die above the buffer die and passing through the first core stack and the second core stack in a second direction, wherein a center of the at least one bridge buffer die has a coordinate corresponding a center of the buffer die; and
a molding layer surrounding the top surface of the buffer die, a side surface of the first core stack, and a side surface of the second core stack,
wherein the at least one bridge buffer die comprises:
a plurality of first pads, a plurality of second pads, and a plurality of first through electrodes in a first region, the plurality of first through electrodes respectively extending from the plurality of first pads to the plurality of second pads, and
a plurality of third pads, a plurality of fourth pads, and a plurality of second through electrodes in a second region, the plurality of second through electrodes respectively extending from the plurality of third pads to the plurality of fourth pads,
wherein the first region overlaps the first core stack in a third direction,
wherein the second region overlaps the second core stack in the third direction,
wherein the first direction is perpendicular to the second direction from a center of the first core stack toward a center of the second core stack,
wherein at least a portion of a first surface of the at least one bridge buffer die and at least a portion of a second surface of the at least one bridge buffer die are surrounded by the molding layer, and
wherein the third direction is perpendicular to the first direction and the second direction.

20. The semiconductor package of claim 19, wherein:
a width of the at least one bridge buffer die is less than a width of the buffer die, and
the width of the at least one bridge buffer die is greater than a width of each of the first core stack and the second core stack.
